(19) United States
(12) Patent Application Publication
(10) Pub. No.: US 2010/0200894 A1
(43) Pub. Date: Aug. 12, 2010

(54) HETERO JUNCTION BIPOLAR TRANSISTOR

(75) Inventors: Yasuyuki Kurita, Toride-shi (JP); Noboru Fukuhara, Tsukuba-shi (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, CHUO-KU, TOKYO (JP)

(21) Appl. No.: 12/670,215

(22) PCT Filed: Jul. 10, 2008
(86) PCT No.: PCT/JP2008/062508

§ 371 Date: Apr. 22, 2010

(30) Foreign Application Priority Data
Jul. 26, 2007 (JP) 2007-194664

(51) Int. Cl. H01L 29/73

(52) U.S. Cl. 257/191; 257/E29.176

(57) ABSTRACT

An energy level Ec in a vicinity of an interface between a graded layer 1G a ballast resistor 1R is smoothly continuous. This is because an n-type impurity concentration C_{ION} in the vicinity of the interface is increased and thus an ionized donor (having a positive charge) exists in the vicinity of the interface. That is, the donor ion cancels out a spike-like potential barrier φ_{BARRIER} protruding in the negative direction of the potential in the vicinity of this interface. Accordingly, the resistance value of an HBT at room temperature decreases and the high frequency characteristics are improved.

### TECHNICAL FIELD

The present invention relates to a hetero junction bipolar transistor (HBT).

### BACKGROUND ART

As the transistor for high speed communication, the hetero junction bipolar transistor (HBT) has been attracting attention. Such high speed communication is desirable particularly in Personal Digital Assistants. In the HBT, an emitter layer and a base layer each comprising a material having a different energy band gap form a hetero junction. In an HBT using a compound semiconductor, the emitter layer, the base layer and a collector layer include AlGaAs, GaAs and GaAs, respectively, for example.

In addition, AlGaAs is a mixed-crystal semiconductor of GaAs and AlAs, wherein the energy band gap of GaAs is 1.4 eV and the energy band gap of AlAs is 2.2 eV, and therefore as the composition ratio of Al in AlGaAs is increased, the energy band gap thereof gradually increases.

In such an HBT, an energy barrier for a hole is formed between the base layer and the emitter layer. Accordingly, usually in the HBT, such an energy barrier is known to increase the emitter injection efficiency of the transistor, and when the emitter injection efficiency is high, high speed operation is possible in the HBT because the resistance value of the transistor can be set low.

However, if a high current flows through the HBT, heat generation occurs due to an interaction between an electron and a semiconductor crystal lattice, or the like. Since this thermal excitation generates free electrons, a higher current will flow through the transistor. That is, if a high current flows through the HBT, a positive feedback action that facilitates an increase of the amount of current will occur, and if this amount of current exceeds an acceptable value of the HBT, the HBT may thermally run away and be destroyed. This is known as a thermal runaway problem of the HBT.

Conventionally, in order to suppress the thermal runaway of the HBT, a technique of connecting a ballast resistor in series to the emitter layer is known. Two methods are known for connecting the ballast resistor. One method is to connect an external ballast resistor in series to an emitter electrode to limit the amount of current. The other one is to insert, when a semiconductor thin film for the HBT is fabricated, a ballast resistor layer comprising a thin film resistor layer in between the emitter electrode and the emitter layer to limit the amount of current (see Patent Document 1, Patent Document 2).

Patent Document 1 employs the latter method, disclosing an example using an Al_{X}Ga_{1-X}As layer as the emitter layer and an Al_{Y}Ga_{1-Y}As layer as a resistor layer constituting the ballast resistor layer. The composition ratio X of Al of the emitter layer is 0.3 while the composition ratio Y of Al of the ballast resistor layer is 0.35. That is, the Al composition ratio Y of the ballast resistor layer is higher than the Al composition ratio X of the emitter layer so that the energy band gap thereof is set to be higher than that of the emitter layer and the ballast resistor layer serves as the energy barrier for an electron.

In the method of Patent Document 1, the resistor layer constituting the ballast resistor layer includes an energy barrier caused by the hetero junction. Namely, a phenomenon is utilized in which the resistance value will increase if a certain energy barrier prevents the electrical conduction, and furthermore in Patent Document 1 the temperature dependence of the ballast resistor layer is set high. Namely, by setting the ballast resistor layer so that the effective mass of an electron conducting through the ballast resistor layer increases as temperature rises, the resistance value at high temperatures is increased so as to exert a thermal runaway suppression function inherent to the ballast resistor layer.

It is known that the smaller the curvature of a graph in the E-k diagram showing a relationship between an energy level E at the bottom of the conduction band and a wave number k (∝1/wavelength of carrier), the heavier the effective mass of an electron becomes. That is, at high temperatures, the electrical conduction just needs to be performed at a position where the curvature on the graph is small. Generally, in the vicinity of an L point, a Γ point, and an X point in the E-k diagram, the energy level E forms an L valley, a Γ valley, and an X valley, respectively, wherein the curvatures of the X valley and L valley are smaller than the curvature of the Γ valley. That is, if there are more electrons in the X valley or the L valley at high temperatures than at room temperature, the resistance will increase at high temperatures. When the X valley and the L valley are positioned on a higher energy side than the Γ valley, then electrons receive thermal energy at high temperatures and there will be more electrons in the X valley and the L valley than at room temperature.

In a case where Al_{Y}Ga_{1-Y}As is used as the ballast resistor layer, if the Al composition ratio Y is 0.45 or lower, then the energy band gap Eg increases in the order from the Γ valley, the L valley, and the X valley, and the closer to 0.45 the Al composition ratio Y becomes, the narrower the spacing of energy levels E of each valley becomes. That is, by approximating the Al composition ratio Y from zero to 0.45 in the ballast resistor, a large number of electrons are allowed to exist in the X valley and L valley each having a small curvature at high temperatures, and accordingly the effective mass of an electron can be increased and the thermal runaway can be suppressed effectively.

Further, in the HBT disclosed in Patent Document 1, a graded layer is interposed between the ballast resistor layer and a GaAs contact layer on the emitter electrode side. The graded layer comprises an Al_{S}Ga_{1-S}As layer, wherein the Al composition ratio S gradually varies along the thickness direction. The Al composition ratio S in the graded layer is set as S=0 at the interface between the graded layer and the contact layer, and is set as S═Y at the interface between the graded layer and the ballast resistor layer. The graded layer suppresses the lattice mismatching associated with a sharp change in the composition. The n-type impurity concentration in the graded layer is constant.

Patent Document 2 discloses an HBT that uses InGaP in addition to AlGaAs as the emitter material. Since the barrier of the InGaP/GaAs hetero junction for a hole is usually larger than that of the AlGaAs/GaAs hetero junction for a hole and the InGaP/GaAs hetero junction also enables manufacturing of a high quality HBT, the emitter injection efficiency is high and the resultant high speed and low power consumption is expected to be achieved.

Moreover, in analysis on the hetero junction, it is also effective to obtain theoretical knowledge by simulation, other than to actually manufacture and evaluate a device.

Patent Document 3 discloses a technique of simulating the carrier current density in the vicinity of the hetero junction interface. With such simulation, the structural analysis and design of the device can be conducted easily and precisely.

Patent Document 1 Japanese Patent No. 3316471

Patent Document 2 Japanese Patent Laid-Open No. 2000-260784

Patent Document 3 Japanese Patent Laid-Open No. 2006-302964

### DISCLOSURE OF THE INVENTION

### Problems to be Solved by the Invention

However, while it is preferable that the resistance value of the ballast resistor increases at high temperatures, the resistance value of the HBT at room temperature at which the normal operation of the HBT is performed is still high and accordingly high frequency characteristics cannot be improved.

The present invention has been made in view of such problems. It is an object of the present invention to provide an HBT capable of improving the high frequency characteristics.

### Means for Solving the Problems

As a result of an intensive study on the HBT, the present inventors have found the generation of a spike-like potential barrier at the interface between a graded layer and a ballast resistor layer. Since such a potential barrier prevents the flow of carriers, the resistance value of the HBT increases and high frequency characteristics degrade. The present invention has been made based on such knowledge, and reduces the resistance value of the HBT at room temperature by removing the above-described potential spike of the HBT by doping an impurity.

In order to solve the above-described problems, an HBT according to the present invention comprises a graded layer whose electron affinity varies continuously and monotonically, wherein when a direction perpendicular to an end face of the graded layer is defined to be a z-axis, and z coordinates of both end faces of the graded layer are denoted by z1 and z2 (where z1<z2), respectively, and an electron affinity and an n-type impurity concentration at a point with the z-coordinate value of z is represented by χ(z), N_{D}(z), respectively, in the both end faces of the graded layer, the electron affinity χ(z) and a rate of change of the electron affinity dχ(z)/dz are continuous in the z direction, and also in the graded layer, the following formula is satisfied: N_{D}(zA) N_{D}(zB) if χ(zA)>χ(zB) (where, z1≦zA≦z2, z1≦zB≦z2).

Further, in p-type impurity, when the p-type impurity concentration at a point with the z-coordinate value of z is denoted by N_{A}(z), in the graded layer, the following formula is satisfied: N_{A}(zA)≧N_{A}(zB), if χ(zA)>χ(zB) (where, z1≦zA≦z2, z1≦zB≦z2).

According to this HBT, in the vicinity of the end face of the graded layer on the side of a smaller electron affinity where a spike-like potential barrier is generated, the concentration of an ionized n-type impurity increases and the spike-like potential barrier decreases due to the charge of this ionized atom. That is, the direction of the potential toward a tip of the spike and the direction of the potential of the ionized atom are opposite to each other. Moreover, the degree of canceling out of the electrostatic potential formed by the charge of the ionized atom and the potential generated by a variation in the electron affinity increases more when the composition variation of the graded layer, i.e., a variation in the electron affinity, is curvedly continuous than when the composition variation of the graded layer is linear. Therefore, the decrease of the spike-like potential barrier is large in the former case. When the variation in the electron affinity is roundedly continuous, the electron affinity χ(z) and the rate of change of the electron affinity dχ(z)/dz are continuous in the z direction on both end faces of the graded layer.

In p-type impurity, only the sign of a charge is opposite to the n-type impurity and therefore the potential variation is opposite to that of the n-type impurity. However, the generation mode of potential barrier is the same in both of the type impurities, and by setting as described above both of the potentials can be canceled out each other as described above to reduce the spike-like potential barrier.

Moreover, when the electron affinity in both of the end faces of the graded layer are denoted by χ1, χ2, respectively; an average dielectric constant of the graded layer is denoted by ∈; z2−z1, is denoted by d; an absolute value of χ1−χ2 is denoted by Δχ; and an elementary electric charge is denoted by q, in n-type impurity, it is preferable that the n-type impurity concentration in the graded layer is equal to or greater than 4∈Δχ/(qd)² in at least a region of (z1+z2)/2≧z≧z2, if χ1>χ2, while the n-type impurity concentration in the graded layer is equal to or greater than 4∈Δχ/(qd)² in at least a region of z1≦z (z1+z2)/2, if χ1<χ2.

In addition, in case of the p-type impurity, it is preferable that the p-type impurity concentration in the graded layer is equal to or greater than 4∈Δχ/(qd)² in at least a region of z1≦z≦(z1+z2)/2, if χ1>χ2, while the p-type impurity concentration in the graded layer is equal to or greater than 4∈Δχ/(qd)² in at least a region of (z1+z2)/2 z≦z2, if χ1<χ2.

In this case, the potential generated by the ionized n-type impurity (or p-type impurity) can sufficiently cancel out the potential spike caused by a difference in the electron affinity.

By (z1+z2)/2=z3, z3 is defined. It is preferable that the electron affinity χ at a point with the z-coordinate value of z of the graded layer satisfies χ=2(z−z1)²(χ2−χ1)/(z2−z1)²+χ1, if z1≦z≦z3 and satisfies χ=−2(z−z2)²(χ2−χ1)/(z2−z1)²+χ2, if z3≦z≦z2. In this case, the electron affinity is expressed as a function consisting of parabolas having opposite polarities, whereby the electron affinity can be smoothly varied along the thickness direction and the electron affinities and their rates of change of the layers adjacent to each other at the interface position can be made continuous.

Further, the graded layer and the ballast resistor layer having a constant electron affinity are preferably included between the emitter electrode and the emitter layer. In this case, since the resistance value of the ballast resistor layer increases at high temperatures and the graded layer absorbs lattice mismatching between the adjacent layers, thermal runaway at high temperatures can be suppressed and an increase of the resistance due to the lattice mismatching can be suppressed.

Furthermore, it is preferable that the ballast resistor layer includes Al_{Y}Ga_{1-Y}As wherein the Al composition ratio Y is a constant value, and that the graded layer includes Al_{S}Ga_{1-S}As wherein the Al composition ratio S varies continuously and monotonically from zero to Y in a direction to approach the ballast resistor layer, and the rate of change of S is zero at the end face of the graded layer. In this case, the composition ratios of the graded layer and the ballast resistor layer are continuous at the interface and the generation of the potential spike will be suppressed.

Moreover, the Al composition ratio Y in the ballast resistor layer preferably satisfies 0<Y≦0.45. In a case where Al_{Y}Ga_{1-Y}As is used as the ballast resistor layer, the energy band gap Eg increases in the order from the Γ valley, the L valley, and the X valley if the Al composition ratio Y is 0.45 or lower, and the closer to 0.45 the Al composition ratio Y becomes, the narrower the spacing of the energy level E of each valley becomes. That is, by approximating the Al composition ratio Y from zero to 0.45 in the ballast resistor, a large number of electrons are allowed to exist in the X valley and L valley each having a small curvature at high temperatures and accordingly the effective mass of an electron can be increased and thermal runaway can be suppressed effectively.

In addition, an HBT according to the present invention is a hetero junction bipolar transistor with a layer structure sequentially stacking between an emitter layer and an emitter electrode: a ballast resistor layer wherein a number of electrons to be excited from a Γ valley to an X valley and an L valley increases with a rise of temperature; and a graded layer whose composition varies, wherein in the vicinity of an interface on a side of the graded layer where the electron affinity is small, the n-type impurity concentration is preferably higher than that in the vicinity of the interface on a side opposite thereto.

The basic structure of the HBT is formed by stacking the collector layer, the base layer, and the emitter layer. The energy band gap of the base layer is smaller than that of the emitter layer so as to increase the emitter injection efficiency. In such an HBT, the ballast resistor layer is interposed between the emitter layer and the emitter electrode. The resistance of the ballast resistor layer increases when the temperature rises, thus suppressing thermal runaway of the HBT. The graded layer absorbs the lattice mismatching between the adjacent semiconductor layers. Here, since the n-type impurity concentration is high in the vicinity of the interface on the side of the graded layer where the electron affinity is small, the potential of the ionized n-type impurity can cancel out the potential spike generated in this interface. As a result, the resistance value of the HBT in operation can be reduced.

Moreover, it is preferable that the ballast resistor layer includes Al_{Y}Ga_{1-Y}As and the graded layer includes Al_{S}Ga_{1-S}As, wherein the Al composition ratio S varies continuously and monotonically from zero to Y in the direction to approach the ballast resistor layer and the Al composition ratio Y satisfies a relationship of 0<Y≦0.45.

In addition, it is preferable that the emitter layer includes Al_{X}Ga_{1-X}As and the Al composition ratio X satisfies X<Y.

AlGaAs is known as a compound semiconductor wherein the energy band gap can be easily controlled by controlling the Al composition ratio. The energy band gap and electron affinity vary when the Al composition ratio S varies continuously from zero to Y. In order to satisfy the relationship of 0<Y≦0.45, the resistance value of the ballast resistor layer increases at high temperatures as described above. Moreover, the energy band gap of the ballast resistor layer is set to be higher than that of the emitter layer so as to serve as a resistance barrier for the emitter layer. The larger the Al composition ratio, the larger the energy band gap becomes. That is, the Al composition ratio of the ballast resistor layer satisfies X<Y. Further, the Al composition ratio Y in the ballast resistor layer may slightly vary.

### EFFECTS OF THE INVENTION

According to the present invention, the high frequency characteristics of the HBT can be improved because the resistance value of the HBT at room temperature can be reduced. Such an HBT is industrially extremely useful.

### BRIEF DESCRIPTION OF THE DRAWINGS

FIG. 1 is a diagram showing a structure of an HBT1 according to an embodiment.

FIG. 2 is a diagram showing an element HBT1′, in which in order to calculate the resistance for an electron of a graded layer 1G a ballast layer 1R, and the emitter layer 1E, a base layer 1B of the HBT1 is replaced with an n-type GaAs layer having a thickness of 100 nm and an impurity concentration of 5×10¹⁸ cm⁻³, and portions from a contact layer 1T to the replaced base layer 1B are extracted, wherein (a) is a diagram showing a structure of semiconductor layers in a vicinity of an emitter layer; (b) is a graph showing the depth direction dependence of an Al composition ratio in each of the semiconductor layers; 2(c) is a graph showing the depth direction dependence of an n-type impurity concentration C_{ION} cm⁻³ in each of the semiconductor layers; and (d) is a graph showing the depth direction dependence of an energy level Ec at the bottom of the conduction band in an Γ valley.

FIG. 3 shows a graph showing a distribution of the n-type impurity concentration C_{ION} along a z-axis direction (a), and shows a graph showing a distribution of an electron concentration C_{ELECTRON} along the z-axis direction (b).

FIG. 4 is a graph showing a distribution in the z-axis direction of a composition ratio S in the graded layer 1G.

FIG. 5 is a diagram showing an HBT according to Comparative Example 1 (in which, as with the first embodiment, in order to calculate the resistance for an electron of the graded layer 1G, the ballast layer 1R, and the emitter layer 1E, the base layer 1B is replaced with the n-type GaAs layer having a thickness of 100 nm and an impurity concentration of 5×10¹⁸ cm⁻³, and portions from the contact layer 1T to the replaced base layer 1B are extracted), wherein (a) is a diagram showing a structure of semiconductor layers in a vicinity of the emitter; (b) is a graph showing the depth direction dependence of the Al composition ratio in each of the semiconductor layers; (c) is a graph showing the depth direction dependence of the n-type impurity concentration C_{ION} cm⁻³ in each of the semiconductor layers; and (d) is a graph showing the depth direction dependence of the energy level Ec at the bottom of the conduction band in the Γ valley.

FIG. 6 is a diagram showing an HBT according to Modification Example 2 (in which, as with the first embodiment, in order to calculate the resistance for an electron of the graded layer 1G the ballast layer 1R, and the emitter layer 1E, the base layer 1B is replaced with the n-type GaAs layer having a thickness of 100 nm and an impurity concentration of 5×10¹⁸ cm⁻³, and portions from the contact layer 1T to the replaced base layer 1B are extracted), wherein (a) is a diagram showing a structure of semiconductor layers in a vicinity of the emitter; (b) is a graph showing the depth direction dependence of the Al composition ratio in each of the semiconductor layers; (c) is a graph showing the depth direction dependence of the n-type impurity concentration C_{ION} cm⁻³ in each of the semiconductor layers; and (d) is a graph showing the depth direction dependence of the energy level Ec at the bottom of the conduction band in the Γ valley.

FIG. 7 is a graph showing the applied voltage VA dependence of a resistance value R in the HBT according to the first embodiment, Comparative Example 1, and Modification Example 2, respectively.

FIG. 8 shows a structure of semiconductor layers in a vicinity of an emitter layer in an HBT2 according to a second embodiment.

FIG. 9 is a graph showing a relationship between a base-emitter voltage Vbe and a collector current Ic.

### DESCRIPTION OF THE REFERENCE SYMBOLS

1 HBT
1T contact layer
1G graded layer
1R ballast resistor layer
1E emitter layer
1B base layer
1C collector layer
1C′ sub-collector layer

### BEST MODES FOR CARRYING OUT THE INVENTION

Hereinafter, HBTs according to the embodiments will be described specifically with reference to the accompanying drawings. The same numerals are used for the same elements to omit the duplicating description.

### First Embodiment

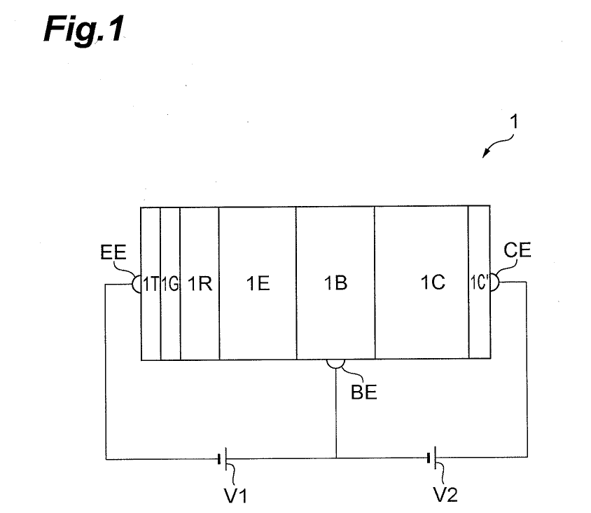

FIG. 1 shows a structure of an HBT1 according to an embodiment.

The HBT1 comprises a collector layer 1C connected to a sub-collector layer 1C′, a base layer 1B connected to the collector layer 1C, and an emitter layer 1E connected to the base layer 1B. A ballast resistor layer 1R is connected to the emitter layer 1E, a graded layer 1G is connected to the ballast resistor layer 1R, and a contact layer 1T is connected to the graded layer 1G. Each of the contact layer 1T, the graded layer 1G the ballast resistor layer 1R, the emitter layer 1E, the base layer 1B, the collector layer 1C, and the sub-collector layer 1C′ includes a semiconductor layer. In this embodiment it includes a III-V group based compound semiconductor layer.

The HBT1 is formed by sequentially stacking onto the sub-collector layer 1C′ the collector layer 1C, the base layer 1B, the emitter layer 1E, the ballast resistor layer 1R wherein the number of electrons excited in an X valley and an L valley increases with a rise of temperature, the graded layer 1G whose composition varies, and the contact layer 1T.

An emitter electrode EE is provided on the contact layer 1T, and these are electrically in contact with each other. A base electrode BE is provided on the base layer 1B, and these are electrically in contact with each other. A collector electrode CE is provided on the sub-collector layer 1C′, and these are also electrically in contact with each other.

A power supply V1 is connected between the emitter electrode EE and the base electrode BE, and a power supply V2 is connected between the base electrode BE and the collector electrode CE. The current flowing through the HBT1 is determined according to the voltage of the power supply V1 providing an emitter-base voltage. The direction (direction perpendicular to the principal surface) parallel to the thickness direction of the semiconductor layers is defined to be the z-axis direction, the position of the exposed surface of the contact layer 1T is defined to be the point of origin, and the direction from this point of origin toward the inside of the semiconductor layers is defined to be the positive direction of the z-axis. The position of the interface between the graded layer 1G and the contact layer 1T is denoted by z1, the position of the interface between the graded layer 1G and the ballast resistor 1R is denoted by z2, and the midpoint position z3 in the z direction in the graded layer 1G is represented by z3=(z1+z2)/2. The position of the interface between the ballast resistor layer 1R and the emitter layer 1E is denoted by z4 and the position of the interface between the emitter 1E and the base 1B is denoted by z5 (where z1<z3<z2<z4<z5).

In the case of an npn-type bipolar transistor, the respective conductivity type, material, thickness, and impurity concentration of the contact layer 1T, the graded layer 1G, the ballast resistor layer 1R, the emitter layer 1E, the base layer 1B, the collector layer 1C, and the sub-collector layer 1C′ are as follows.
Contact layer 1T:

conductivity type: n-type

material: GaAs

thickness T_{1T}: 100 nm

n-type impurity concentration C_{1T}: 5×10¹⁸ cm⁻³
Graded layer 1G:

conductivity type: n-type

material: Al_{S}Ga_{1-S}As

thickness T_{1G}: 20 nm

n-type impurity concentration C_{1G}: 5×10¹⁶ cm⁻³ (z1≦z≦z3)

n-type impurity concentration C_{1G}: 1.87×10¹⁸ cm⁻³ (z3≦z≦z2)
Ballast resistor layer 1R:

conductivity type: n-type

material: Al_{Y}Ga_{1-Y}As

thickness T_{1R}: 200 nm

n-type impurity concentration C_{1R}: 5×10¹⁶ cm⁻³
Emitter layer 1E:

conductivity type: n-type

material: Al_{X}Ga_{1-X}As

thickness T_{1E}: 50 nm

n-type impurity concentration C_{1E}: 5×10¹⁷ cm⁻³
Base layer 1B:

conductivity type: p-type

material: GaAs

thickness T_{1B}: 80 nm

p-type impurity concentration C_{1B}: 2×10¹⁹ cm⁻³
Collector layer 1C:

conductivity type: n-type

material: GaAs

thickness T_{1C}: 700 nm

n-type impurity concentration C_{1C}: 2×10¹⁶ cm⁻³
Sub-collector layer 1C′:

conductivity type: n-type

material: GaAs

thickness T_{1C}: 500 nm

n-type impurity concentration C_{1C}: 5×10¹⁸ cm⁻³

The composition ratio S of Al contained in the graded layer 1G, the composition ratio Y of Al contained in the ballast resistor layer 1R, and the composition ratio X of Al contained in the emitter layer 1E in this embodiment are as follows.

Al composition ratio in the graded layer S=0 to 0.35

Al composition ratio in the ballast resistor layer Y=0.35

Al composition ratio in the emitter layer X=0.3

An example of the numerical value range for suitably operating as the HBT is as follows. Moreover, the present invention is not limited to the embodiment.

50 nm≦T_{1T}≦200 nm

1×10¹⁸ cm⁻³≦C_{1T}≦6×10¹⁸ cm⁻³

10 nm≦T_{1G}≦100 nm

1×10¹⁶ cm⁻³≦C_{1G}≦3×10¹⁸ cm⁻³

100 nm≦T_{1R}≦300 nm

1×10¹⁶ cm⁻³≦C_{1R}≦1×10¹⁸ cm⁻³

20 nm≦T_{1E}≦200 nm

1×10¹⁶ cm⁻³≦C_{1E}≦1×10¹⁸ cm⁻³

50 nm≦T_{1B}≦200 nm

1×10¹⁹ cm⁻³≦C_{1B}≦5×10¹⁹ cm⁻³

200 nm T_{1C}≦1000 nm

5×10¹⁵ cm⁻³≦C_{1C}≦5×10¹⁷ cm⁻³

50 nm≦T_{1C′}≦1000 nm

1×10¹⁸ cm⁻³≦C_{1C′}≦6×10¹⁸ cm⁻³

0<Y≦0.45

0.1≦X≦0.4

When Al_{Y}Ga_{1-Y}As is employed as the material of the ballast resistor layer 1R, the Al composition ratio Y in the layer is preferably set to be constant. The Al composition ratio Y is preferably greater than zero and no greater than 0.45 so that with a rise of temperature the electrons in the ballast resistor layer 1R are excited from the Γ valley to the X valley and L valley each having a lower electron mobility than that of the Γ valley, thereby obtaining the effect of increasing the resistance and suppressing thermal runaway.

In the below, a simulation of the element HBT1′ is performed, wherein in order to calculate the resistance for an electron of the graded layer 1G, ballast layer 1R, and emitter layer 1E, the base layer 1B is replaced with the n-type GaAs layer having a thickness of 100 nm and an impurity concentration of 5×10¹⁸ cm⁻³, and portions from the contact layer 1T to the replaced base layer 1B are extracted.

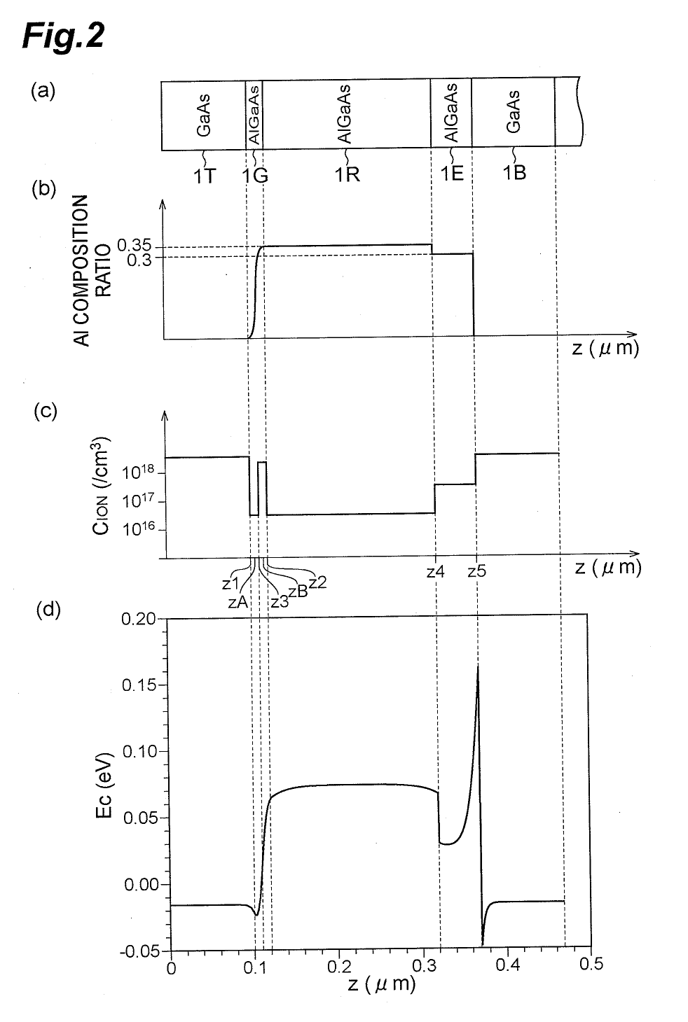

FIG. 2-(a) shows a structure of semiconductor layers in the vicinity of the emitter layer in the HBT1′ according to the above-described embodiment. FIG. 2-(b) is a graph showing the depth direction dependence of the Al composition ratio in each of the semiconductor layers. FIG. 2-(c) is a graph showing the depth direction dependence of the impurity concentration C_{ION} cm⁻³ in each of the semiconductor layers. FIG. 2-(d) is a graph showing the depth direction dependence of the energy level Ec at the bottom of the conduction band in the Γ valley. In addition, FIG. 2-(d) shows a result of calculating the energy level Ec by simulation when the bias voltage is not supplied to the HBT1′.

As shown in FIG. 2-(b), in the graded layer 1G, the second-order derivative value (d²S/dz²) by the depth z of the Al composition ratio S is positive in a range of z1 to z3 and is negative in a range of z3 to z2. Moreover, as shown in FIG. 2-(c), in the depth of z3 to z2, the n-type impurity concentration C_{ION} in the graded layer 1G is higher than that in the ballast resistor 1R while in the depth of z1 to z3, it is lower than that in the depth of z3 to z2.

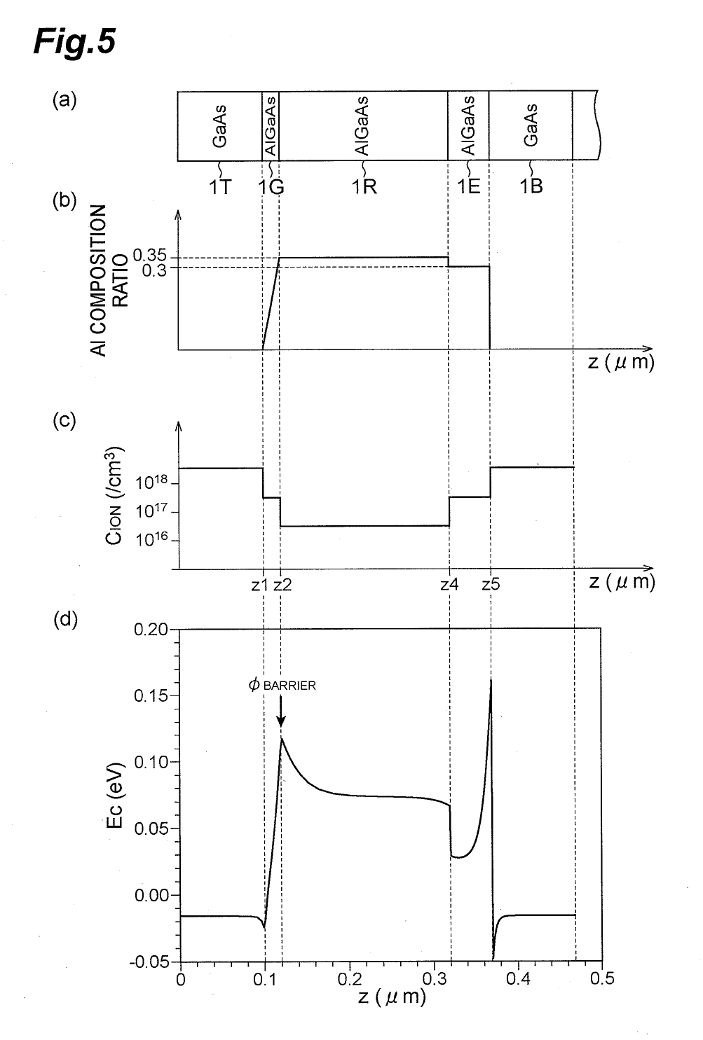

The energy level Ec in the vicinity of the interface between the graded layer 1G and the ballast resistor 1R according to the embodiment is smoothly continuous. This is because the n-type impurity concentration C_{ION} in the vicinity of the interface is increased and as a result an ionized donor (having a positive charge) exists in the vicinity of the interface. That is, the donor ion cancels out the spike-like potential barrier φ_{BARRIER} (see FIG. 5-(d)) that protrudes in the negative direction of the potential in the vicinity of this interface. In addition, the positive or negative direction of the potential is opposite to the positive or negative direction of the energy level.

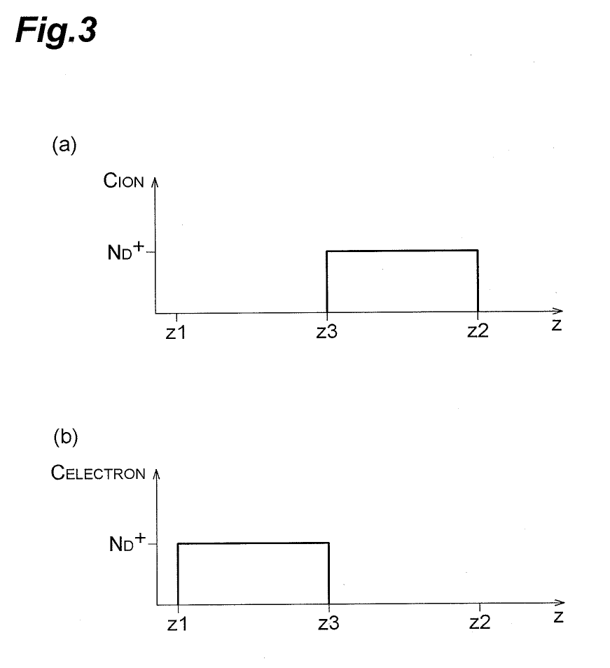

FIG. 3-(a) is a graph showing a distribution of the n-type impurity concentration C_{ION} along the z-axis direction and FIG. 3-(b) is a graph showing a distribution of the electron concentration C_{ELECTRON} along the z-axis direction.

With regard to the concentration of ionized n-type impurity C_{ION}, C_{ION} satisfies a formula: C_{ION}=N_{D}+ at the depth z in the range of z3≦z≦z2. Further, the concentration of electrons C_{ELECTRON} satisfies a formula: C_{ELECTRON}=N_{D}⁺ at the depth z in the range of z1≦z<z3. In the range of z3≦z≦z2, the presence of the ionized impurity adjusts the spike of the energy level Ec shown in FIG. 5(d) downwardly and reduces the resistance of the HBT in use.

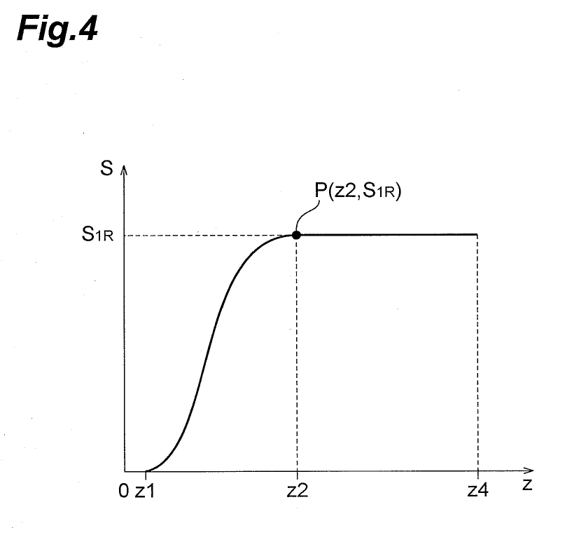

FIG. 4 is a graph showing a distribution in the z-axis direction of the composition ratio S in the above-described graded layer 1G.

The composition ratio S in the graded layer is approximately represented by the following formulas.

z1≦z≦z3:S=A(z−z1)²

z3≦z≦z2:S=−A(z−z2)²+B

z1=100 nm

z2=120 nm

z3=110 nm

A=0.00175

B=0.35

The composition ratio S is a function of z, and this function draws a downwardly convex parabola in the range of z1≦z≦z3 in the z-S plane and draws an upwardly convex parabola in the range of z3≦z≦z2, thus monotonously increasing. The composition ratio S satisfies S=S_{1R} in the region of z2≦z≦z4, and is set as S_{1R}=0.35 in this embodiment.

The function of the composition ratio S is also as follows:

S=0.175[1−cos {π(z−z1)/(z2−z1)}] 1)

z1≦z≦z3:S=A(z−z1)²/(z2−z1)(z3−z1) 2)

z3≦z≦z2:S=A{1−(z−z2)²/(z2−z1)(z2−z3)}

z1=100 nm

z2=120 nm

100 nm<z3<120 nm

A=0.35

In this case, the n-type impurity concentration shall be equal to or greater than 2∈Δχ/q²(z2−z1)(z2−z3) at least in the region of z3≦z≦z2. Where ∈ is the average dielectric constant in the graded layer, Δχ is the absolute value of χ1−χ2, χ1 and χ2 are the electron affinity at the points with the z-coordinate values of z1 and z2, respectively, and q is the elementary electric charge.

The HBT1′ of the first embodiment described above is formed by stacking an AlGaAs graded layer whose Al composition S varies in the form of a parabola from zero to 0.35 (the n-type impurity concentration is 5×10¹⁶ cm⁻³ for 10 nm on the Al composition S=0 side and is 4∈Δχ/(qd)²+5×10¹⁶=1.87×10¹⁸ cm⁻³ for 10 nm on the Al composition S=0.35 side, and the total layer thickness is 20 nm), an AlGaAs ballast layer whose Al composition is 0.35 (the n-type impurity concentration is 5×10¹⁶ cm⁻³ and the layer thickness is 200 nm), and an AlGaAs emitter layer whose Al composition is 0.3 (the n-type impurity concentration is 5×10¹⁷ cm⁻³ and the layer thickness is 50 nm), wherein the both ends of these layers are sandwiched by the GaAs contact layer 1T having an n-type impurity concentration of 5×10¹⁸ cm⁻³ and a layer thickness of 100 nm and the replaced GaAs base layer 1B.

FIG. 2-(d) shows a result of calculating the shape of the bottom of the conduction band at the voltage 0 V by semiconductor device simulation, wherein there is no spike-like potential barrier in the vicinity of the interface between the graded layer 1G and the ballast layer 1R.

### Comparative Example 1

FIG. 5 shows an HBT according to Comparative Example 1 (in which, as with the first embodiment, in order to calculate the resistance for an electron of the graded layer 1G, the ballast layer 1R, and the emitter layer 1E, the base layer 1B is replaced with the n-type GaAs layer having a thickness of 100 nm and an impurity concentration of 5×10¹⁸ cm⁻³, and portions from the contact layer 1T to the replaced base layer 1B are extracted), wherein FIG. 5-(a) is a diagram showing a structure of semiconductor layers in a vicinity of the emitter; FIG. 5-(b) is a graph showing the depth direction dependence of the Al composition ratio in each of the semiconductor layers; FIG. 5-(c) is a graph showing the depth direction dependence of the n-type impurity concentration C_{ION} cm⁻³ in each of the semiconductor layers; and FIG. 5-(d) is a graph showing the depth direction dependence of the energy level Ec at the bottom of the conduction band in the Γ valley. In addition, FIG. 5-(d) shows a result of calculating the energy level Ec by simulation when the bias voltage is not supplied to the HBT.

As shown in FIG. 5-(b), in the graded layer 1G the Al composition ratio S is proportional to the depth z, and as shown in FIG. 5-(c), the n-type impurity concentration C_{ION} in the graded layer 1G is constant. The n-type impurity concentration in the graded layer 1G is 5×10¹⁷ cm⁻³. Other structures are the same as those of the HBT of the first embodiment.

In the HBT according to Comparative Example 1, at the interface between the graded layer 1G and the ballast resistor 1R, the spike-like potential barrier φ_{BARRIER} is generated in the energy level Ec at the bottom of the conduction band.

The spike-like potential barrier φ_{BARRIER} increases the emitter resistance of the HBT and degrades the high frequency characteristics.

The cause of generation of the spike-like potential barrier φ_{BARRIER} is a difference in the electron affinity χ between the ballast resistor 1R (Al composition ratio Y=0.35) and the graded layer 1G (Al composition ratio S=k×z+m: k and m are constants).

The electron affinity χ is an energy difference between at the vacuum level and at the bottom of the conduction band, and generally, the smaller the energy band gap, the larger the electron affinity χ becomes. By assuming the vacuum level of two semiconductors constituting the hetero structure is the same energy, a relationship between the energy band gaps of two semiconductors is determined from the electron affinity and the band gap of each of the semiconductors.

Due to the electrons flowing from the ballast resistor 1R having a small electron affinity χ_{1R} into the graded layer 1G having a high electron affinity χ_{1G}, the concentration of electrons in the ballast resistor 1R decreases as approaching the graded layer 1G. That is, the energy difference between the electron quasi-Fermi level and the energy level Ec at the bottom of the conduction band increases; however, since the electron quasi-Fermi level is constant without current flowing, the energy level Ec at the bottom of the conduction band will rise as approaching the graded layer 1G (see FIG. 5-(d)).

In the HBT according to Comparative Example 1, the graded layer 1G (the n-type impurity concentration is 5×10¹⁷ cm⁻³ and the layer thickness is 20 nm) whose Al composition linearly varies from zero to 0.35, the AlGaAs ballast layer 1R whose Al composition is 0.35 (the n-type impurity concentration is 5×10¹⁶ cm⁻³ and the layer thickness is 200 nm), and the AlGaAs emitter layer whose Al composition is 0.3 (the n-type impurity concentration is 5×10¹⁷ cm⁻³ and the layer thickness is 50 nm) are stacked. These layers are sandwiched by the GaAs contact layer 1T having an n-type impurity concentration of 5×10¹⁸ cm⁻³ and a layer thickness of 100 nm and the replaced base layer 1B. FIG. 5-(d) shows a result of calculating the bottom shape of the conduction band at the voltage 0 V by semiconductor device simulation. There is the spike-like potential barrier φ_{BARRIER} in the vicinity of the interface between the graded layer 1G and the ballast layer 1R.

### Modification Example 2

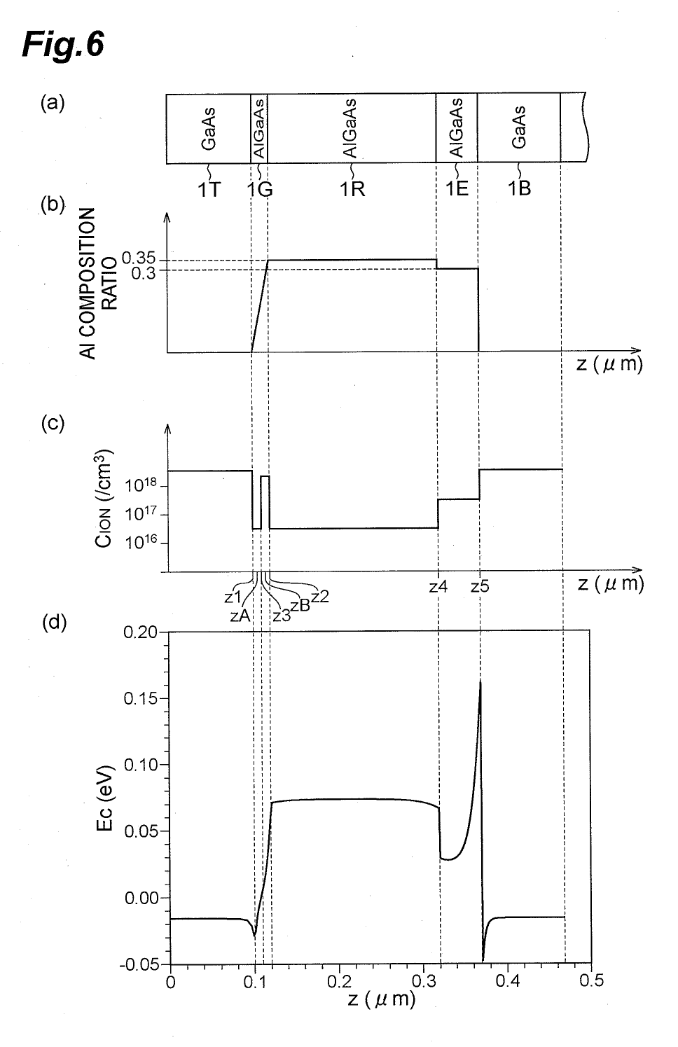

FIG. 6 shows an HBT according to Modification Example 2 (in which, as with the first embodiment, in order to calculate the resistance for an electron of the graded layer 1G, the ballast layer 1R, and the emitter layer 1E, the base layer 1B is replaced with the n-type GaAs layer having a thickness of 100 nm and an impurity concentration of 5×10¹⁸ cm⁻³, and portions from the contact layer 1T to the replaced base layer 1B are extracted), wherein FIG. 6-(a) is a diagram showing a structure of semiconductor layers in a vicinity of the emitter; FIG. 6-(b) is a graph showing the depth direction dependence of the Al composition ratio in each of the semiconductor layers; FIG. 6-(c) is a graph showing the depth direction dependence of the n-type impurity concentration C_{ION} cm⁻³ in each of the semiconductor layers; and FIG. 6-(d) is a graph showing the depth direction dependence of the energy level Ec at the bottom of the conduction band in the Γ valley. In addition, FIG. 6-(d) shows a result of calculating the energy level Ec by simulation when the bias voltage is not supplied to the HBT.

The AlGaAs graded layer 1G whose Al composition linearly varies from zero to 0.35 (the n-type impurity concentration is 5×10¹⁶ cm⁻³ for 10 nm on the Al composition S=0 side and is 4∈Δχ/(qd)²+5×10¹⁶=1.87×10¹⁸ cm⁻³ for 10 nm on the Al composition S=0.35 side, and the total layer thickness is 20 nm), the AlGaAs ballast layer 1R whose Al composition is 0.35 (the n-type impurity concentration is 5×10¹⁶ cm⁻³ and the layer thickness is 200 nm), and the AlGaAs emitter layer 1E whose Al composition is 0.3 (the n-type impurity concentration is 5×10¹⁷ cm⁻³ and the layer thickness is 50 nm) are stacked.

These layers are sandwiched by the contact layer 1T comprising GaAs having an n-type impurity concentration of 5×10¹⁸ cm⁻³ and a layer thickness of 100 nm and the replaced base layer 1B.

Although there is no spike-like potential barrier in the vicinity of the interface between the graded layer and the ballast layer, a portion having a larger potential gradient than that in the case of the modulation-doped parabolic graded layer structure of the first embodiment is long and thus the resistance value is large. This result indicates that a combination of the modulation dope and the parabolic variation of the electron affinity is important.

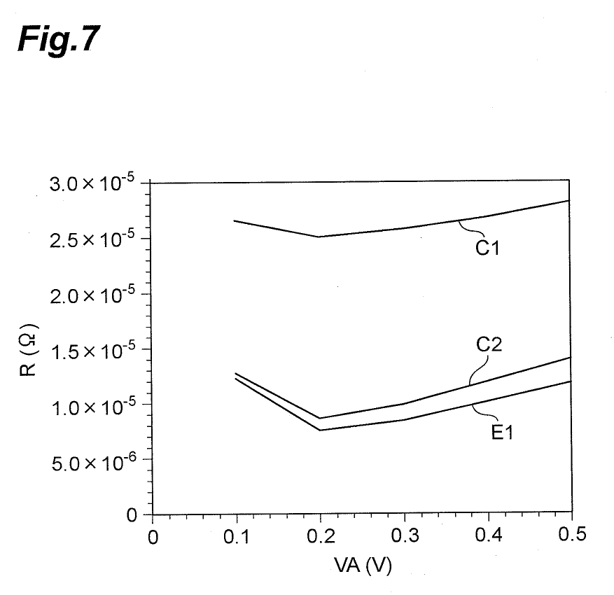

FIG. 7 is a graph showing the applied voltage VA dependence of the resistance value R in the HBT according to the first embodiment, Comparative Example 1, and Modification Example 2. The applied voltage VA is a voltage (in a range of 0.1 to 0.5 V) between an end face 1TC on the opposite side of the graded layer 1G of the contact layer 1T, the end face 1TC being used as the reference, and an end face on the opposite side of the emitter layer 1E of the replaced base layer 1B. The cross sectional area of the element of each layer is 1 cm².

The resistance value R indicated by data E1 of the HBT according to the first embodiment is smaller than data C1 and C2 of the HBTs having the linear graded layer structures shown in FIG. 5 and FIG. 6. Moreover, the resistance values indicated by data E1 of the first embodiment having the modulation dope in the vicinity of the interface of the graded layer 1G and the data C2 of the HBT shown in FIG. 6 are smaller than the resistance value indicated by the data C1 of the HBT of Comparative Example 1.

In the HBT1 of the first embodiment shown in FIG. 2, the n-type impurity concentration in the vicinity area of the potential barrier φ_{BARRIER} in the graded layer 1G i.e., the region where the electron affinity χ is small, is set high, and thus the height of the spike-like potential barrier φ_{BARRIER} shown in FIG. 5 for an electron decreases. In the HBT1 according to the first embodiment, since the positive charge of the ionized n-type impurity stabilizes the electron having a negative charge, the height of the spike-like potential barrier φ_{BARRIER} for an electron is small (see FIG. 2-(d)).

Moreover, in the HBT1 of the first embodiment, the potential shape, which the positive charge of the n-type impurity ionized in the graded layer 1G and the electron flowing from the ballast resistor 1R of a small electron affinity χ_{1R} into the graded layer 1G form, is approximately parabolic. The rate of change of the potential is continuous at the interface between the ballast resistor 1R and the graded layer 1G and therefore, if the rate of change of the electron affinity is also continuous, canceling out of the variation of the electron affinity by the potential becomes better.

### Second Embodiment

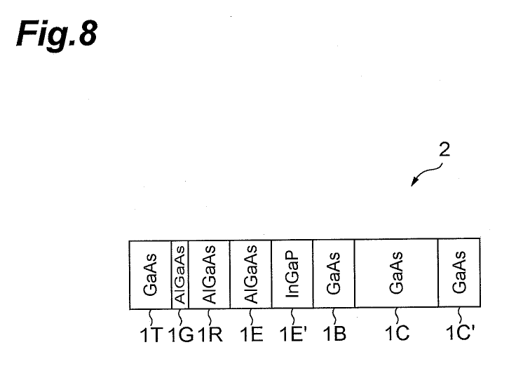

FIG. 8 shows a structure of semiconductor layers in the vicinity of the emitter layer in an HBT2 according to a second embodiment. In the HBT2, an n⁺-type GaAs contact layer (cap layer) 1T (the n-type impurity concentration is 5×10¹⁸ cm⁻³ and the layer thickness is 100 nm), a graded AlGaAs layer 1G whose Al composition ratio varies in the above-described form of a parabola from zero to 0.35 (the n-type impurity concentration ratio is 5×10¹⁶ cm⁻³ for 10 nm on the Al composition ratio S=0 side and is 4∈Δχ/(qd)²+5×10¹⁶=1.87×10¹⁸ cm⁻³ for 10 nm on the Al composition S=0.35 side, and the total thickness is 20 nm), the AlGaAs ballast layer 1R whose Al composition ratio is 0.35 (the n-type impurity concentration is 5×10¹⁶ cm⁻³ and the layer thickness is 200 nm), a first AlGaAs emitter layer 1E whose Al composition ratio is 0.3 (the n-type impurity concentration is 5×10¹⁷ cm⁻³ and the layer thickness is 50 nm), a second emitter layer 1E′ comprising InGaP (the n-type impurity concentration is 5×10¹⁷ cm⁻³, the layer thickness is 40 nm, In composition ratio is 0.48), a p⁺-type GaAs base layer 1B (the p-type impurity concentration is 2×10¹⁹ cm⁻³ and the layer thickness is 80 nm), the GaAs collector layer 1C (the n-type impurity concentration is 2×10¹⁶ cm⁻³ and the layer thickness is 700 nm), and a GaAs sub-collector layer 1C′ (the n-type impurity concentration is 5×10¹⁸ cm⁻³ and the layer thickness is 500 nm) are stacked.

The HBT2 of the second embodiment differs from the HBT1 of the first embodiment in that InGaP is used as the second emitter layer 1E′, and other structures are the same. The emitter area is 2.4×20 μm².

In addition, the HBTs of the structures of Comparative Example 3 and Comparative Example 4 described below were also studied for comparison.

### Comparative Example 3

In the HBT of Comparative Example 3, the n⁺-type GaAs contact layer 1T (the n-type impurity concentration is 5×10¹⁸ cm⁻³ and the thickness is 100 nm), the AlGaAs graded layer 1G whose Al composition ratio linearly varies from zero to 0.35 (the n-type impurity concentration is 5×10¹⁷ cm⁻³, the layer thickness is 20 nm), the AlGaAs ballast layer 1R whose Al composition ratio is 0.35 (the n-type impurity concentration is 5×10¹⁶ cm⁻³ and the layer thickness is 200 nm), the first AlGaAs emitter layer 1E whose Al composition ratio is 0.3 (the n-type impurity concentration is 5×10¹⁷ cm⁻³ and the layer thickness is 50 nm), the second InGaP emitter layer 1E′ (the n-type impurity concentration is 5×10¹⁷ cm⁻³, the layer thickness is 40 nm, In composition ratio is 0.48), the p⁺-type GaAs base layer 1B (the p-type impurity concentration is 2×10¹⁹ cm⁻³ and the layer thickness is 80 nm), the GaAs collector layer 1C (the n-type impurity concentration is 2×10¹⁶ cm⁻³ and the layer thickness is 700 nm), and the GaAs sub-collector layer 1C′ (the n-type impurity concentration is 5×10¹⁸ cm⁻³ and the layer thickness is 500 nm) are stacked. The emitter area is 2.4×20 μm².

### Comparative Example 4

In the HBT of Comparative Example 4, the n⁺-type GaAs contact layer 1T (the n-type impurity concentration is 5×10¹⁸ cm⁻³ and the layer thickness is 100 nm), a GaAs layer (the n-type impurity concentration is 5×10¹⁷ cm⁻³ and the layer thickness is 20 nm), a GaAs layer (n-type impurity concentration is 5×10¹⁶ cm⁻³, thickness is 200 nm), a GaAs layer (the n-type impurity concentration is 5×10¹⁷ cm⁻³ and the layer thickness is 50 nm), an InGaP emitter layer (the n-type impurity concentration is 5×10¹⁷ cm⁻³, the layer thickness is 40 nm, In composition ratio is 0.48), a p⁺-type GaAs base layer (the p-type impurity concentration is 2×10¹⁹ cm⁻³ and the layer thickness is 80 nm), a GaAs collector layer (the n-type impurity concentration is 2×10¹⁶ cm⁻³ and the layer thickness is 700 nm), and a GaAs sub-collector layer (the n-type impurity concentration is 5×10¹⁸ cm⁻³ and the layer thickness is 500 nm) are stacked. The emitter area is 2.4×20 μm².

In the HBTs of the second embodiment, Comparative Example 3, and Comparative Example 4, a relationship of the base-emitter voltage Vbe and the collector current Ic at a collector-emitter voltage of 5 V was calculated by semiconductor device simulation taking the heat generation and heat flow into consideration.

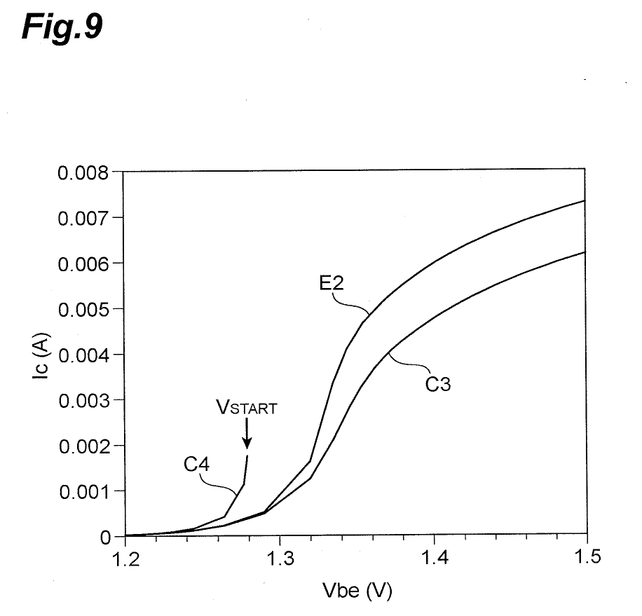

FIG. 9 is a graph showing the relationship of the base-emitter voltage Vbe and the collector current Ic.

In the HBT of the second embodiment (data E2), thermal runaway is suppressed by the ballast resistor layer. Moreover, in the HBT of the second embodiment (data E2), we find that the collector current Ic is larger and the resistance is smaller than in the HBT of Comparative Example 3 (data C3) having the linear graded ballast layer structure.

In the HBT of Comparative Example 3 (data C3), we find that although thermal runaway is suppressed by the ballast resistor layer, the collector current Ic is small and the resistance is large as compared with the modulation-doped parabolic-graded ballast structure of the second embodiment (data E2).

In the HBT of Comparative Example 4 (data C4), when the voltage exceeds V_{START}, thermal runaway occurs because there is no AlGaAs ballast layer.

Next, the potential in the vicinity of the interface between the graded layer 1G and the ballast resistor layer 1R is described in detail.

The electron affinity at the depth z=z1 is denoted by χ1 and the electron affinity at the depth z=z2 is denoted by χ2 (where χ1>χ2). The region at the depth of z3 to z2 in the graded layer 1G is a ballast resistor side region having a small electron affinity, and the region at the depth of z1 to z3 is a contact layer side region having a large electron affinity. As shown in FIG. 3, the n-type impurity concentration in the ballast resistor side region (z3 to z2) is set to be higher than that in the contact layer side region (z1 to z3).

The potential φ at the position of z=z1 is defined to be the reference potential (φ=1). As the electrostatic potential φ_{(z1 to z3)} in the range of z1≦z≦z3 and the electrostatic potential φ_{(z3 to z2)} in the range of z3≦z≦z2, Formulas (2), (3) are derived from Poisson's equation (1). Moreover, Formulas (3-1) and (3-2) are derived from the fact that dφ/dz and φ are continuous.

$$\begin{matrix}- \frac{{d}^{2} φ}{d {z}^{2}} = \frac{ρ}{ɛ} & ( 1 ) \\ {φ}_{( z 1 \sim z 3 )} = \frac{{{qN}_{D}^{+} ( z - z 1 )}^{2}}{2 ɛ} & ( 2 ) \\ {φ}_{( z 3 \sim z 2 )} = - \frac{{{qN}_{D}^{+} ( z - z 2 )}^{2}}{2 ɛ} + z \times C + {C}^{′} & ( 3 ) \\ C = 0 & ( 3 \text{-} 1 ) \\ {C}^{′} = \frac{{{qN}_{D}^{+} ( z 2 - z 1 )}^{2}}{4 ɛ} & ( 3 \text{-} 2 ) \\ {N}_{D}^{+} = \frac{4 ɛΔ χ}{{( qd )}^{2} } & ( 3 \text{-} 3 ) \\ d = z 2 - z 1 & ( 3 \text{-} 4 )\end{matrix}$$

Where each parameter is as follows.

φ: electrostatic potential

ρ: charge density

∈: dielectric constant

q: elementary electric charge

N_{D}⁺: concentration of ionized n-type impurity (concentration of electrons flowing into the low energy side)

C: constant

C′: constant

d: thickness of graded layer

Since C′ is a potential difference between both ends of the graded layer, the electron affinity difference can be cancelled out by setting as qC′=Δχ. Where Δχ=χ1−χ2. That is, Formula (3-3) and Formula (3-4) just need to be satisfied.

Substitution of Formulas (3-1) to (3-4) into Formulas (2) and (3) gives Formula (4) and Formula (5). Moreover, an energy difference ΔE (with respect to the energy at z=z1 as the reference) that is generated when the potential acts on an electron is −qφ.

Accordingly, the energy difference ΔE_{(z1 to z3)} in the range of the depth of z1 to z3 satisfies Formula (6), and the energy difference ΔE_{(z3 to z2)} in the range of the depth of z3 to z2 satisfies Formula (7).

On the other hand, when the electron affinity χ_{(z1 to z3)} in the range of the depth of z1 to z3 satisfies Formula (8) and the electron affinity χ_{(z3 to 22)} in the range of the depth of z3 to z2 satisfies Formula (9), an energy difference ΔE′_{(z1-z3)} in the range of the depth of z1 to z3, with the energy at z=z1 as the reference, due to the variation in the electron affinity satisfies Formula (10) and the energy difference ΔE′_{(z3 to z2)} in the range of the depth of z3 to z2 satisfies Formula (11).

$$\begin{matrix}{φ}_{( z 1 \sim z 3 )} = \frac{2 {( z - z 1 )}^{2} ( χ 1 - χ 2 )}{{q ( z 2 - z 1 )}^{2}} & ( 4 ) \\ {φ}_{( z 3 \sim z 2 )} = - \frac{2 {( z - z 2 )}^{2} ( χ 1 - χ 2 )}{{q ( z 2 - z 1 )}^{2}} + \frac{( χ 1 - χ 2 )}{q} & ( 5 ) \\ Δ {E}_{( z 1 \sim z 3 )} = \frac{2 {( z - z 1 )}^{2} ( χ 2 - χ 1 )}{{( z 2 - z 1 )}^{2}} & ( 6 ) \\ Δ {E}_{( z 3 \sim z 2 )} = - \frac{2 {( z - z 2 )}^{2} ( χ 2 - χ 1 )}{{( z 2 - z 1 )}^{2}} + ( χ 2 - χ 1 ) & ( 7 ) \\ {χ}_{( z 1 \sim z 3 )} = \frac{2 {( z - z 1 )}^{2} ( χ 2 - χ 1 )}{{( z 2 - z 1 )}^{2}} + χ 1 & ( 8 ) \\ {χ}_{( z 3 \sim z 2 )} = - \frac{2 {( z - z 2 )}^{2} ( χ 2 - χ 1 )}{{( z 2 - z 1 )}^{2}} + χ 2 & ( 9 ) \\ Δ {E}_{( z 1 \sim z 3 )}^{′} = - \frac{2 {( z - z 1 )}^{2} ( χ 2 - χ1 )}{{( z 2 - z 1 )}^{2} } & ( 10 ) \\ Δ {E}_{( z 3 \sim z 2 )}^{′} = \frac{2 {( z - z 2 )}^{2} ( χ 2 - χ 1 )}{{( z 2 - z 1 )}^{2}} + χ 1 - χ 2 & ( 11 )\end{matrix}$$

These ΔE′ and ΔE cancel out each other. That is, ΔE+ΔE′=0.

Accordingly, the n-type impurity concentration C_{1G(z1 to z3)} in the contact layer side region (in the range of z1≦z≦z3) of the graded layer 1G and the n-type impurity concentration C_{1G(z3 to z2)} in the ballast resistor side region (in a range of z3≦z≦z2) in the graded layer 1G are set as the following Formulas (12-1) to (12-4) with N_{D}′ as an appropriate constant.

$$\begin{matrix}( A ) if χ 1 > χ 2 , \\ {C}_{1 G ( z 1 \sim z 3 )} = {N}_{D}^{′} & ( 12 \text{-} 1 ) \\ {C}_{1 G ( z 3 \sim z 2 )} = \frac{4 ɛ Δ χ}{( qd ) 2} + {N}_{D}^{′} \\ ( B ) if χ1 < χ 2 , & ( 12 \text{-} 2 ) \\ {C}_{1 G ( z 1 \sim z 3 )} = \frac{4 ɛΔ χ}{( qd ) 2} + {N}_{D}^{′} & ( 12 \text{-} 3 ) \\ {C}_{1 G ( z 3 \sim z 2 )} = {N}_{D}^{′} & ( 12 \text{-} 4 )\end{matrix}$$

As the Al composition ratio S in the graded layer 1G is varied, the energy band gap and electron affinity χ will vary. If the function in the thickness direction z of the composition ratio S is a parabola, then the function in the thickness direction z of the electron affinity χ is also a parabola. If the function of the electron affinity χ is parabolic as described above, then the energy difference between both ends of the graded layer due to the electron affinity difference will be canceled out by the energy difference caused by the charge distribution, and therefore the generation of the spike-like potential barrier φ_{BARRIER} caused by the electron affinity difference is suppressed.

Moreover, also when the n-type impurity concentration C_{1G} of the whole graded layer 1G is set equal to or greater than 4∈Δχ/(qd)², the electron flows from a high energy side into a low energy side and the ionization rate of the n-type impurity concentration decreases on the low energy side, and therefore a similar charge distribution is obtained to suppress the generation of the spike-like potential barrier.

By applying the above-described structure of the graded layer 1G to the ballast resistor 1R inserted between the emitter electrode EE and the emitter 1E, the generation of the spike-like potential barrier φ_{BARRIER} is suppressed and the emitter resistance causing a degradation in the high frequency characteristics can be reduced.

The ballast resistor 1R does not necessarily need to be the AlGaAs layer and may be an InAlGaAs layer or the like. When the ballast resistor 1R is the InAlGaAs layer, the graded layer 1G interposed between the contact layer 1T comprising the GaAs layer and the ballast resistor 1R has the electron affinity that varies in the above-described form of a parabola. Therefore, the ballast resistor 1R just needs to have such an n-type impurity concentration distribution that cancels out the potential variation due to the electron affinity.

As described above, the HBTs according to the above-described embodiments include the graded layer 1G whose electron affinity varies continuously and monotonously, as shown in FIGS. 2(a) to 2(d), and when the direction perpendicular to the end face of the graded layer 1G is defined as the z-axis, and the z coordinates of both end faces of the graded layer 1G are denoted as z1, z2 (where z1<z2), respectively, and the electron affinity and the n-type impurity concentration at the point with the z-coordinate value of z is represented by χ(z), N_{D}(z), respectively, then in the both end faces of the graded layer, the electron affinity χ(z) and the rate of change of the electron affinity dχ(z)/dz are continuous in the z direction, and also in the graded layer, N_{D}(zA)≦N_{D}(zB), if χ(zA)>χ(zB).

As shown in FIG. 2-(c), positions ZA and ZB in the z direction satisfy a relationship of z1≦zA≦z2 and z1≦zB≦z2.

According to the HBT1, in the vicinity of the end face of the graded layer on the side of a smaller electron affinity where the spike-like potential barrier is generated, the concentration of the ionized n-type impurity C_{ION} increases (see FIG. 2-(c)) and the spike-like potential barrier decreases due to the charge of this ionized atom. That is, the direction of the potential toward a tip of the spike and the direction of the potential of the ionized atom are opposite to each other. Moreover, the degree of canceling out of the electrostatic potential formed by the ionized atomic charge and the potential generated by the variation in the electron affinity becomes larger when the composition variation of the graded layer 1G, i.e., the variation in the electron affinity, is curvedly continuous than when the composition variation of the graded layer 1G is linear, and therefore, the decrease in the spike-like potential barrier is larger when the composition variation of the graded layer 1G is curvedly continuous. When the variation in the electron affinity is curvedly continuous, the electron affinity χ(z) and the rate of change of the electron affinity dχ(z)/dz are continuous in the z direction on both end faces of the graded layer 1G.

Moreover, when the electron affinities in both of the end faces of the graded layer 1G are denoted by χ1, χ2, respectively, the average dielectric constant of the graded layer 1G is denoted by ∈, z2−z1 is denoted by d, the absolute value of χ1−χ2 is denoted by Δχ, and the elementary electric charge is denoted by q, then it is preferable that the n-type impurity concentration in the graded layer is equal to or greater than 4∈Δχ/(qd)² in at least a region of (z1+z2)/2≦z≦z2 if χ1>χ2 while the impurity concentration in the graded layer is equal to or greater than 4∈Δχ/(qd)² in at least a region of z1≦z≦(z1+z2)/2, if χ1<χ2. (See Formula (12-1) to Formula (12-4)).

In this case, the potential generated by the ionized impurity can sufficiently cancel out the potential spike caused by a difference in the electron affinity.

As described above, (z1+z2)/2=z3. The electron affinity χ at the point with the z-coordinate value of z of the graded layer preferably satisfies Formula (8) and Formula (9). In this case, the electron affinity is expressed as a function consisting of parabolas having opposite polarities, and whereby the electron affinity can be smoothly varied along the thickness direction and the electron affinities and their rates of change of the layers adjacent at the interface position can be made continuous.

Moreover, the above-described HBT1 includes the graded layer 1G and the ballast resistor layer 1R having a constant electron affinity between the emitter electrode EE and the emitter layer 1E. In this case, since the resistance value of the ballast resistor layer 1R increases at high temperatures and the graded layer 1G absorbs lattice mismatching between the adjacent layers, thermal runaway at high temperatures can be suppressed and an increase of the resistance due to the lattice mismatching can be suppressed.

Moreover, it is preferable that the ballast resistor layer 1R includes Al_{Y}Ga_{1-Y}As wherein the Al composition ratio Y is a constant value, and the graded layer includes Al_{S}Ga_{1-S}As wherein the Al composition ratio S varies continuously and monotonically from zero to Y in the direction to approach the ballast resistor layer. In this case, the composition ratios of the graded layer 1G and the ballast resistor layer 1R are continuous at the interface and the generation of the potential spike will be suppressed.

Moreover, the Al composition ratio Y in the ballast resistor layer 1R preferably satisfies 0<Y≦0.45. When Al_{Y}Ga_{1-Y}As is used as the ballast resistor layer 1R, the energy band gap Eg increases in the order from the Γ valley, the L valley, and the X valley if the Al composition ratio Y is 0.45 or lower, and the closer to 0.45 the Al composition ratio Y becomes, the narrower the spacing of the energy level E of each valley becomes. That is, by approximating the Al composition ratio Y from zero to 0.45 in the ballast resistor, a large number of electrons are allowed to exist in the X valley and L valley each having a small curvature at high temperatures and accordingly the effective mass of an electron can be increased and thermal runaway can be suppressed effectively.

Moreover, the above-described HBT1 comprises: the base layer 1B, the emitter layer 1E; the ballast resistor layer 1R wherein the number of electrons excited in the X valley and the L valley increases with a rise of temperature; the graded layer 1G whose composition varies; and the contact layer 1T, sequentially stacked on the collector layer 1T. Here, in the vicinity of the interface on a side of the graded layer 1G where the electron affinity is small, the n-type impurity concentration is set to be higher than that in the vicinity of the interface on a side opposite thereto.

The basic structure of the HBT1 is formed by stacking the collector layer 1C, the base layer 1B, and the emitter layer 1E. The energy band gap of the base layer 1B is smaller than that of the emitter layer 1E, and whereby the emitter injection efficiency becomes high. The ballast resistor layer 1R suppresses thermal runaway of the HBT1 because the resistance thereof increases when the temperature rises. The graded layer 1G absorbs the lattice mismatching between the contact layer 1T and the ballast resistor layer 1R. Here, since the n-type impurity concentration is high in the vicinity of the interface on the side of the graded layer 1G where the electron affinity is small, the potential of the ionized impurity can cancel out the potential spike generated in this interface. Accordingly, the resistance value of the HBT1 in operation can be reduced.

Moreover, it is preferable that the emitter layer 1E includes Al_{X}Ga_{1-X}As, the ballast resistor layer 1R includes Al_{Y}Ga_{1-Y}As, the graded layer 1G includes Al_{S}Ga_{1-S}As, the Al composition ratio S varies continuously and monotonically from zero to Y in the direction to approach the ballast resistor layer, the Al composition ratio Y satisfies a relationship of 0<Y≦0.45, and the Al composition ratio X satisfies X<Y.

AlGaAs is known as a compound semiconductor wherein the energy band gap can be easily controlled by controlling the Al composition ratio. As the Al composition ratio S varies continuously from zero to Y, the energy band gap and electron affinity vary. In order to satisfy the relationship of 0<Y≦0.45, the resistance value of the ballast resistor layer 1R increases at high temperatures as described above. Moreover, the energy band gap of the ballast resistor layer 1R is set to be higher than that of the emitter layer 1E so as to serve as a resistance barrier for the emitter layer 1E. The larger the Al composition ratio, the larger the energy band gap becomes. That is, the Al composition ratio of the ballast resistor layer 1R satisfies X<Y. Note that the Al composition ratio Y in the ballast resistor layer 1R may not be constant but may vary slightly.

In addition, in the above, an npn bipolar transistor wherein the conductivity types of the emitter, base, and collector are an n-type, a p-type, and an n-type, respectively, has been described, however, a pnp bipolar transistor wherein the conductivity types of the emitter, base, and collector are a p-type, an n-type, and a p-type, respectively, is also possible. That is, in the case of the pnp transistor, in the above-described description, the n-type impurity is read as the p type impurity, only the sign of a charge is opposite to the above-described one, as the ionized impurity an acceptor exists instead of a donor, and the spike-like potential barrier will occur in the opposite direction. However, the function of the transistor is the same as the above-described one.

In this manner, it is preferable that if the p-type impurity concentration at a point with the z-coordinate value of z is denoted by NA(z) when the impurity in the graded layer is a p-type impurity, in the graded layer, N_{A}(zA)≧N_{A}(zB) if χ(zA)>χ(zB) (where, z1≦zA≦z2, z1≦zB≦z2). When the impurity is a p-type impurity, only the sign of a charge is opposite to the n-type impurity and therefore the potential variation is opposite to that of the n-type impurity. However, the condition of generation of the potential barrier in the n-type impurity is the same as one the p-type impurity; and thus, by setting as described above the spike-like potential barrier can be reduced by canceling out the both potentials.

Moreover, when the impurity in the graded layer is a p-type impurity, it is preferable that the p-type impurity concentration in the graded layer is equal to or greater than 4∈Δχ/(qd)², at least in a region of z1≦z≦(z1+z2)/2, if χ1>χ2 while the p-type impurity concentration in the graded layer is equal to or greater than 4∈Δχ/(qd)² in at least a region of (z1+z2)/2≦z≦z2, if χ1<χ2. In this case, the potential generated by the ionized p-type impurity can sufficiently cancel out the potential spike caused by a difference in the electron affinity.

1. A hetero junction bipolar transistor comprising a graded layer whose electron affinity varies continuously and monotonically,
wherein when a direction perpendicular to an end face of the graded layer is defined to be a z-axis, and z coordinates of both end faces of the graded layer are denoted by z1, z2, respectively, where z1<z2, and an electron affinity at a point with the z-coordinate value of z is represented by χ(z),
the electron affinity χ(z) and a rate of change of the electron affinity dχ(z)/dz are continuous in the z direction at the both end faces of the graded layer; and
when χ(zA)>χ(zB) in the graded layer,
where z1≦zA≦z2, and
z1≦zB≦z2,
N_{D}(z), which is an impurity concentration when the impurity having been added at a point with the z-coordinate value of z is an n-type impurity, and satisfiles:
N_{D}(zA)≦N_{D}(zB), and
N_{A}(z), which is an impurity concentration when the impurity having been added at the point with the z-coordinate value of z is a p-type impurity, and satisfies:
N_{A}(zA)≧N_{A}(zB).

2. The hetero junction bipolar transistor according to claim 1,
wherein
the electron affinity in the both end faces of the graded layer are denoted by χ1, χ2, respectively;
an average dielectric constant of the graded layer is denoted by ∈;
z2−z1 is denoted by d;
an absolute value of χ1−χ2 is denoted by Δχ; and
an elementary electric charge is denoted by q,
an impurity concentration in the graded layer is equal to or greater than 4∈Δχ/(qd)² in at least a region of (z1+z2)/2≦z≦z2, when χ1>χ2 and the impurity type is an n-type,
an impurity concentration in the graded layer is equal to or greater than 4∈Δχ/(qd)² in at least a region of z1≦z≦(z1+z2)/2, when χ1>χ2 and the impurity type is a p-type,
the impurity concentration in the graded layer is equal to or greater than 4∈Δχ/(qd)² in at least a region of z1≦z≦(z1+z2)/2, when χ1<χ2 and the impurity type is an n-type, and
the impurity concentration in the graded layer is equal to or greater than 4∈Δχ/(qd)² in at least a region of (z1+z2)/2≦z≦z2, when χ1<χ2 and the impurity type is a p-type.

3. The hetero junction bipolar transistor according to claim 2, wherein
the electron affinity χ at a point with the z-coordinate value of z in the graded layer
satisfies:
χ=2(z−z1)²(χ2−χ1)/(z2−z1)²+χ1, if z1≦z≦(z1+z2)/2, and
satisfies:
χ=−2(z−z2)²(χ2−χ1)/(z2−z1)²+χ2, if (z1+z2)/2≦z≦z2.

4. The hetero junction bipolar transistor according to claim 1, comprising the graded layer and a ballast resistor layer having a constant electron affinity between an emitter electrode and an emitter layer.

5. The hetero junction bipolar transistor according to claim 4, wherein
the ballast resistor layer includes Al_{Y}Ga_{1-Y}As; and
an Al composition ratio Y is a constant value;
the graded layer includes Al_{S}Ga_{1-S}As; and
an Al composition ratio S varies continuously and monotonically from zero to Y in a direction to approach the ballast resistor layer.

6. The hetero junction bipolar transistor according to claim 5, wherein the Al composition ratio Y in the ballast resistor layer satisfies 0<Y≦0.45.

7. A hetero junction bipolar transistor with a layer structure sequentially stacking between an emitter layer and an emitter electrode: a ballast resistor layer wherein the number of excited electrons increases from a Γ valley to an X valley and an L valley with a rise of temperature; and a graded layer whose composition varies, wherein
in a vicinity of an interface on a side of the graded layer where an electron affinity is small, an n-type impurity concentration is higher than that in a vicinity of an interface on a side opposite thereto.

8. The hetero junction bipolar transistor according to claim 7: wherein
the ballast resistor layer includes Al_{Y}Ga_{1-Y}As;
the graded layer includes Al_{S}Ga_{1-S}As;
an Al composition ratio S varies continuously and monotonically from zero to Y in a direction to approach the ballast resistor layer; and
an Al composition ratio Y satisfies a relationship of 0<Y≦0.45.

9. The hetero junction bipolar transistor according to claim 8,
wherein
the emitter layer includes Al_{X}Ga_{1-X}As, and
an Al composition ratio X satisfies X<Y.
